(19) United States
(12) Patent Application Publication
(10) Pub. No.: US 2009/0140408 A1
(43) Pub. Date: Jun. 4, 2009

(54) INTEGRATED CIRCUIT PACKAGE-ON-PACKAGE SYSTEM WITH STACKING VIA INTERCONNECT

(76) Inventors: Taewoo Lee, Icheon-Si (KR); Sang-Ho Lee, Kyounggi (KR); Soo-San Park, Seoul (KR)

Correspondence Address: LAW OFFICES OF MIKIO ISHIMARU, 333 W. EL CAMINO REAL, SUITE 330, SUNNYVALE, CA, 94087, US

(21) Appl. No.: 11/948,060

(22) Filed: Nov. 30, 2007

(51) Int. Cl. H01L 23/48; H01L 21/58

(52) U.S. Cl. 257/686; 438/109; 257/E23.01; 257/E21.505

(57) ABSTRACT

An integrated circuit package-on-package system includes: providing a bottom integrated circuit package system having a bottom substrate; mounting a top integrated circuit package system having a top substrate over the bottom integrated circuit package system; forming a top stacking via through the top substrate; forming a bottom stacking via into the bottom integrated circuit package system to the bottom substrate; and forming a stacking via interconnect with the top stacking via and the bottom stacking via aligned and connected.

### TECHNICAL FIELD

The present invention relates generally to an integrated circuit package system and more particularly to an integrated circuit package-on-package system.

### BACKGROUND ART

To interface an integrated circuit with other circuitry, it is common to mount it on a lead frame or substrate. Each integrated circuit has bonding pads that are individually connected to the lead frame's lead finger pads using extremely fine gold or aluminum wires. The assemblies are then packaged by individually encapsulating them in molded plastic or ceramic bodies to create an integrated circuit package.

Integrated circuit packaging technology has seen an increase in the number of integrated circuits mounted on a single circuit board or substrate. The new packaging designs are more compact in form factors, such as the physical size and shape of an integrated circuit, and providing a significant increase in overall integrated circuit density.

However, integrated circuit density continues to be limited by the “real estate” available for mounting individual integrated circuits on a substrate. Even larger form factor systems, such as PC's, compute servers, and storage servers, need more integrated circuits in the same or smaller “real estate”. Particularly acute, the needs for portable personal electronics, such as cell phones, digital cameras, music players, PDA's, and location-based devices, have further driven the need for integrated circuit density.

This increased integrated circuit density, has led to the development of multi-chip packages in which more than one integrated circuit can be packaged. Each package provides mechanical support for the individual integrated circuits and one or more layers of interconnect lines that enable the integrated circuits to be connected electrically to surrounding circuitry.

Current multi-chip packages, also commonly referred to as multi-chip modules, typically consist of one or more substrates onto each of which one or more integrated circuit components is directly attached. Such multi-chip packages have been found to increase integrated circuit density and miniaturization, improve signal propagation speed, reduce overall integrated circuit size and weight, improve performance, and lower costs—all primary goals of the computer industry.

Among other problems encountered with these multi-chip and multi-chip modules is connecting different packages together to form a single module. There are design limitations presented by package stacks as well. In many of the stacked structures, the top package is not able to have system interconnects in the center as this area is usually consumed by the plastic package cover of the lower device. In the push for more integrated function, this limitation may stop a design from using the package type.

Multi-chip packages whether vertically or horizontally arranged, can also present problems because they usually must be pre-assembled before the integrated circuit and integrated circuit connections can be tested. Thus, when integrated circuits are mounted and connected in a multi-chip module, individual integrated circuits and connections cannot be tested individually, and it is not possible to identify known-good-die (“KGD”) before being assembled into larger circuits. Consequently, conventional multi-chip packages lead to assembly process yield problems. This fabrication process, which does not identify KGD, is therefore less reliable and more prone to assembly defects.

Moreover, vertically stacked integrated circuits in typical multi-chip packages can present problems beyond those of horizontally arranged integrated circuit packages, further complicating the manufacturing process. It is more difficult to test and thus determine the actual failure mode of the individual integrated circuits. Moreover, the substrate and integrated circuit are often damaged during assembly or testing, complicating the manufacturing process and increasing costs.

For both vertical and horizontal multi-chip packages, assembly of the multi-chip packages must have reliable electrical and mechanical attachments between the multiple integrated circuits, the stacked packaged integrated circuits, or a combination thereof. This becomes especially challenging when manufacturing of multi-chip packages attempts to balance KGD by testing the individual packages before stacking and forming finer pitch interconnects between the stacked packages.

Thus, a need still remains for an integrated circuit package-on-package system providing low cost manufacturing, improved yield, improved reliability, and greater flexibility to offer more functionality and fewer footprints on the printed circuit board. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit package-on-package system including: providing a bottom integrated circuit package system having a bottom substrate; mounting a top integrated circuit package system having a top substrate over the bottom integrated circuit package system; forming a top stacking via through the top substrate; forming a bottom stacking via into the bottom integrated circuit package system to the bottom substrate; and forming a stacking via interconnect with the top stacking via and the bottom stacking via aligned and connected.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a top view of an integrated circuit package-on-package system in a first embodiment of the present invention;

FIG. 2 is a cross-sectional view of the integrated circuit package-on-package system along line 2-2 of FIG. 1;

FIG. 3 is a cross-sectional view of an integrated circuit package-on-package system exemplified by the top view of FIG. 1 in a second embodiment of the present invention;

FIG. 4 is a top view of an integrated circuit package-on-package system in a third embodiment of the present invention;

FIG. 5 is a cross-sectional view of the integrated circuit package-on-package system along line 5-5 of FIG. 4;

FIG. 6 is a top view of an integrated circuit package-on-package system in a fourth embodiment of the present invention;

FIG. 7 is a cross-sectional view of the integrated circuit package-on-package system along line 7-7 of FIG. 6;

FIG. 8 is a cross-sectional view of an integrated circuit package-on-package system exemplified by the top view of FIG. 6 in a fifth embodiment of the present invention;

FIG. 9 is a cross-sectional view of the integrated circuit package-on-package system of FIG. 3 in a step of forming the bottom integrated circuit package system;

FIG. 10 is the structure of FIG. 9 in a step of forming bottom channels;

FIG. 11 is the structure of FIG. 10 in a step of applying the adhesive and attaching the external interconnects;

FIG. 12 is the structure of FIG. 11 in a step of mounting the top integrated circuit package system;

FIG. 13 is the structure of FIG. 12 in a step of plating the channels;

FIG. 14 is the structure of FIG. 9 in a step of attaching the external interconnects;

FIG. 15 is the structure of FIG. 14 in a step of mounting the top integrated circuit package system;

FIG. 16 is the structure of FIG. 15 in a step of forming the channels;

FIG. 17 is the structure of FIG. 16 in a step of plating the channels; and

FIG. 18 is a flow chart of an integrated circuit package-on-package system for manufacturing of the integrated circuit package-on-package system in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs. Generally, the invention can be operated in any orientation.

In addition, where multiple embodiments are disclosed and described having some features in common, for clarity and ease of illustration, description, and comprehension thereof, similar and like features from one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material, patterning, exposure, development, etching, cleaning, molding, and/or removal of the material or as required in forming a described structure. The term “system” as used herein means and refers to the method and to the apparatus of the present invention in accordance with the context in which the term is used.

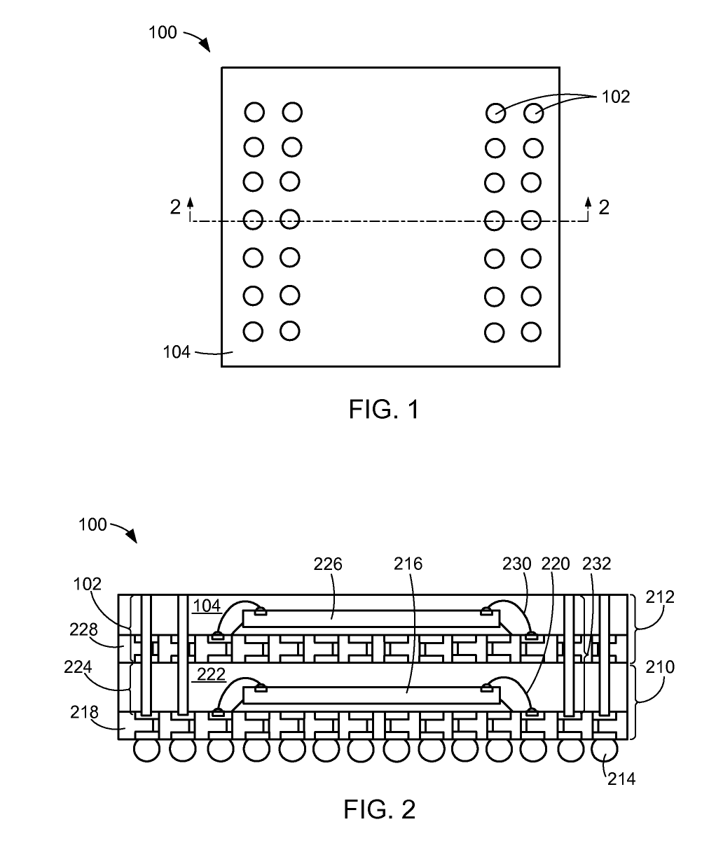

Referring now to FIG. 1, therein is shown a top view of an integrated circuit package-on-package system 100 in a first embodiment of the present invention. The top view depicts top stacking vias 102 along the periphery of a top encapsulation 104, such as an encapsulation formed from an epoxy molding compound. For illustrative purposes, the integrated circuit package-on-package system 100 is shown with the top stacking vias 102 along the peripheral region of the top encapsulation 104, although it is understood that the top stacking vias 102 may not be along the peripheral region of the top encapsulation 104. For example, the top stacking vias 102 may be placed towards or at a central region of the top encapsulation 104.

Referring now to FIG. 2, therein is shown a cross-sectional view of the integrated circuit package-on-package system 100 along line 2-2 of FIG. 1. The cross-sectional view depicts a bottom integrated circuit package system 210 stacked below a top integrated circuit package system 212. External interconnects 214, such as solder balls, may attach below the bottom integrated circuit package system 210.

The bottom integrated circuit package system 210 includes a first integrated circuit 216, such as an integrated circuit die, mounted over a bottom substrate 218. First internal interconnects 220, such as bond wires or ribbon bond wires, connect the first integrated circuit 216 and the bottom substrate 218. A bottom encapsulation 222, such as an encapsulation formed from an epoxy molding compound, cover the first integrated circuit 216 and the first internal interconnects 220 over the bottom substrate 218. Bottom stacking vias 224 extend from a conductive portion, such as a contact pad or trace, of the bottom substrate 218 through a top side of the bottom encapsulation 222. The external interconnects 214 attach to and below the bottom substrate 218.

The top integrated circuit package system 212 includes a second integrated circuit 226, such as an integrated circuit die, mounted over a top substrate 228. Second internal interconnects 230, such as bond wires or ribbon bond wires, connect the second integrated circuit 226 and the top substrate 228. The top encapsulation 104 covers the second integrated circuit 226 and the second internal interconnects 230 over the top substrate 228. The top stacking vias 102 extend from a top side of the top encapsulation 104 through the top substrate 228 and connecting to the bottom stacking vias 224. The top stacking vias 102 connected and aligned with the bottom stacking vias 224 forming stacking via interconnects 232.

It has been discovered that the present invention provides an integrated circuit package-on-package system reducing package height and increasing electrical connectivity with the stacking via interconnects 232. The stacking via interconnects may eliminate solder balls between the top package and the bottom package thereby eliminating the reflow that would be associated with the solder balls. The stacking via interconnects may be formed with finer pitch than the pitch available with the solder balls increasing the electrical connectivity between the top package and bottom package. The stacking via interconnects also provide additional flexibility of stacking integrated circuit packages by eliminating constrains that one of the package may be inverted or other conductive interposers to provide electrical connectivity.

For illustrative purposes, the top integrated circuit package system 212 and the bottom integrated circuit package system 210 are shown similar in structure, although it is understood that the top integrated circuit package system 212 and the bottom integrated circuit package system 210 may not be similar. For example, the first integrated circuit 216 and the second integrated circuit 226 may be different size, functions, technologies, or configurations such as stacked integrated circuits. As another example, the top integrated circuit package system 212 and the bottom integrated circuit package system 210 may be different sizes.

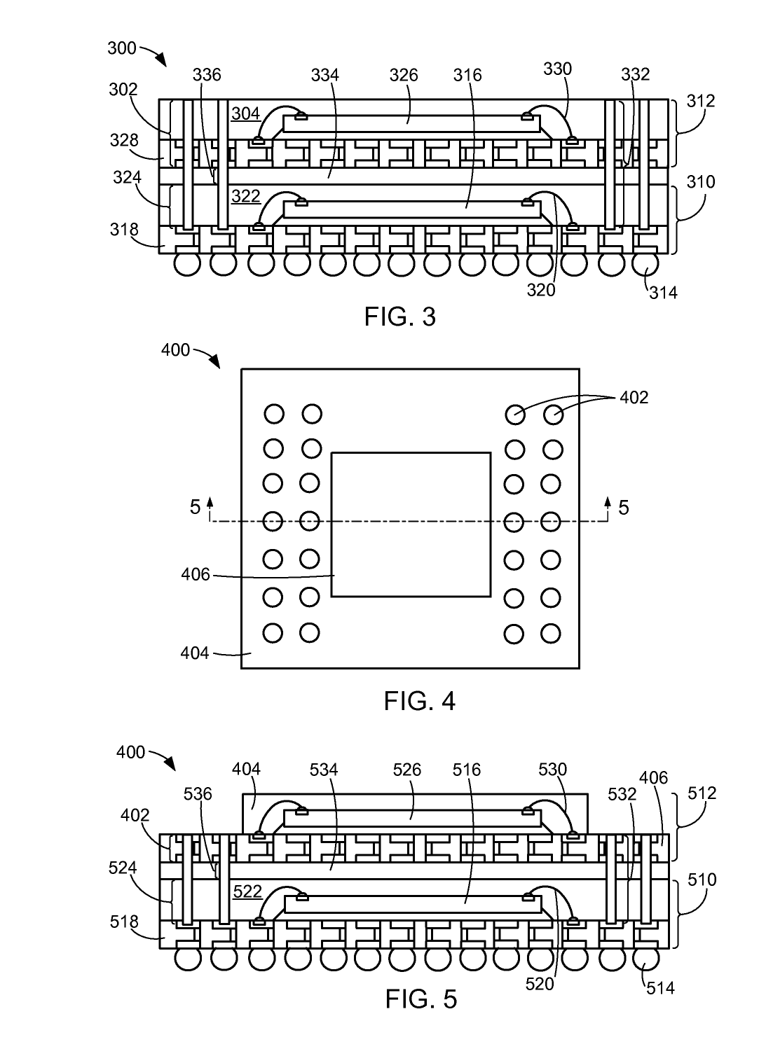

Referring now to FIG. 3, therein is shown a cross-sectional view of an integrated circuit package-on-package system 300 exemplified by the top view of FIG. 1 in a second embodiment of the present invention. The integrated circuit package-on-package system 300 has structural similarities to the integrated circuit package-on-package system 100 of FIG. 2. The cross-sectional view depicts a bottom integrated circuit package system 310 stacked below a top integrated circuit package system 312. External interconnects 314, such as solder balls, may attach below the bottom integrated circuit package system 310.

The bottom integrated circuit package system 310 includes a first integrated circuit 316 mounted over a bottom substrate 318. First internal interconnects 320, connect the first integrated circuit 316 and the bottom substrate 318. A bottom encapsulation 322 cover the first integrated circuit 316 and the first internal interconnects 320 over the bottom substrate 318. Bottom stacking vias 324 extend from a conductive portion, such as a contact pad or trace, of the bottom substrate 318 through a top side of the bottom encapsulation 322. The external interconnects 314 attach to and below the bottom substrate 318.

An adhesive 334, such as a film adhesive, is applied over the top side of the bottom encapsulation 322. The adhesive 334 have connecting vias 336 aligned with the bottom stacking vias 324. The adhesive 334 may provide mechanical rigidity to the structure of the integrated circuit package-on-package system 300.

The top integrated circuit package system 312 includes a second integrated circuit 326 mounted over a top substrate 328. Second internal interconnects 330, such as bond wires or ribbon bond wires, connect the second integrated circuit 326 and the top substrate 328. A top encapsulation 304 covers the second integrated circuit 326 and the second internal interconnects 330 over the top substrate 328. Top stacking vias 302 extend from a top side of the top encapsulation 304 through the top substrate 328. The top stacking vias 302 is connected and aligned with the connecting vias 336 which is connected and aligned with the bottom stacking vias 324 forming stacking via interconnects 332.

Referring now to FIG. 4, therein is shown a top view of an integrated circuit package-on-package system 400 in a third embodiment of the present invention. The top view depicts top stacking vias 402 in a top substrate 406. A top encapsulation 404, such as an encapsulation formed from an epoxy molding compound, may be over the top substrate 406 and not covering the top stacking vias 402.

For illustrative purposes, the integrated circuit package-on-package system 100 is shown with the top stacking vias 402 in the top substrate 406, although it is understood that the top stacking vias 402 may not be in different locations. For example, the top stacking vias 402 may be placed in the top encapsulation 404.

Referring now to FIG. 5, therein is shown a cross-sectional view of the integrated circuit package-on-package system 400 along line 5-5 of FIG. 4. The cross-sectional view depicts a bottom integrated circuit package system 510 stacked below a top integrated circuit package system 512. External interconnects 514, such as solder balls, may attach below the bottom integrated circuit package system 510.

The bottom integrated circuit package system 510 includes a first integrated circuit 516, such as an integrated circuit die, mounted over a bottom substrate 518. First internal interconnects 520, such as bond wires or ribbon bond wires, connect the first integrated circuit 516 and the bottom substrate 518. A bottom encapsulation 522, such as an encapsulation formed from an epoxy molding compound, covers the first integrated circuit 516 and the first internal interconnects 520 over the bottom substrate 518. Bottom stacking vias 524 extend from a conductive portion, such as a contact pad or trace, of the bottom substrate 518 through a top side of the bottom encapsulation 522. The external interconnects 514 attach to and below the bottom substrate 518.

An adhesive 534, such as a film adhesive, is applied over the top side of the bottom encapsulation 522. The adhesive 534 have connecting vias 536 aligned with the bottom stacking vias 524. The adhesive 534 may provide mechanical rigidity to the structure of the integrated circuit package-on-package system 400.

The top integrated circuit package system 512 includes a second integrated circuit 526 mounted over the top substrate 406. Second internal interconnects 530, such as bond wires or ribbon bond wires, connect the second integrated circuit 526 and the top substrate 406. The top encapsulation 404 covers the second integrated circuit 526 and the second internal interconnects 530 over the top substrate 406. The top encapsulation 404 may not cover the top stacking vias 402. The top stacking vias 402 may extend from a top side of and through the top substrate 406. The top stacking vias 402 is connected and aligned with the connecting vias 536 which is connected and aligned with the bottom stacking vias 524 forming stacking via interconnects 532.

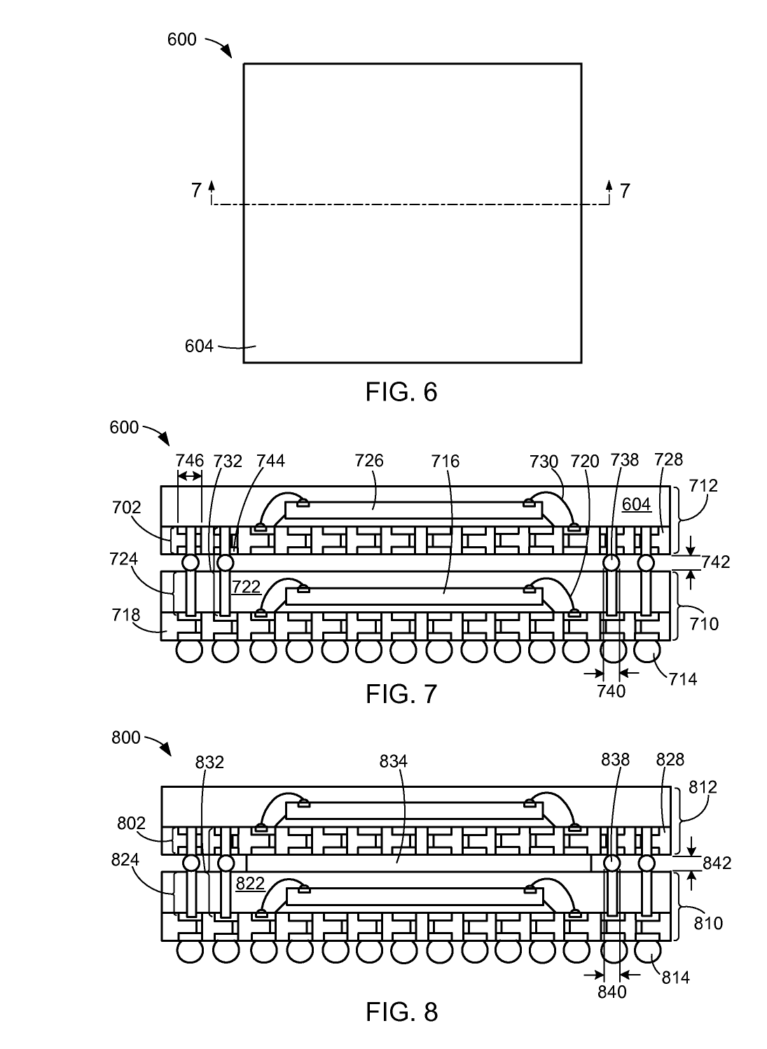

Referring now to FIG. 6, therein is shown a top view of an integrated circuit package-on-package system 600 in a fourth embodiment of the present invention. The top view depicts a top encapsulation 604, such as an encapsulation formed from an epoxy molding compound. For illustrative purposes, the top encapsulation 604 is shown in a geometric shape of a square, although it is understood that the top encapsulation 604 may be formed in different geometric shape, such as a rectangle or a square with obtuse corners.

Referring now to FIG. 7, therein is shown a cross-sectional view of the integrated circuit package-on-package system 600 along line 7-7 of FIG. 6. The cross-sectional view depicts a bottom integrated circuit package system 710 stacked below a top integrated circuit package system 712. External interconnects 714, such as solder balls, may attach below the bottom integrated circuit package system 710.

The bottom integrated circuit package system 710 includes a first integrated circuit 716, such as an integrated circuit die, mounted over a bottom substrate 718. First internal interconnects 720, such as bond wires or ribbon bond wires, connect the first integrated circuit 716 and the bottom substrate 718. A bottom encapsulation 722, such as an encapsulation formed from an epoxy molding compound, covers the first integrated circuit 716 and the first internal interconnects 720 over the bottom substrate 718. Bottom stacking vias 724 extend from a conductive portion, such as a contact pad or trace, of the bottom substrate 718 through a top side of the bottom encapsulation 722. The external interconnects 714 attach to and below the bottom substrate 718.

Conductive bumps 738, such as micro bumps, is applied over the bottom stacking vias 724. Each of the conductive bumps 738 has a bump width 740. The conductive bumps 738 may provide a number of functions. For example, the conductive bumps 738 provide electrical connection between the top integrated circuit package system 712 and the bottom integrated circuit package system 710. The conductive bumps 738 may also provide a gap 742 between the top integrated circuit package system 712 and the bottom integrated circuit package system 710 for airflow for helping cool the integrated circuit package-on-package system 600. The bump width 740 is approximately the same as a bottom via width of the bottom stacking vias 724.

The top integrated circuit package system 712 includes a second integrated circuit 726 mounted over a top substrate 728. Second internal interconnects 730, such as bond wires or ribbon bond wires, connect the second integrated circuit 726 and the top substrate 728. The top encapsulation 604 covers the second integrated circuit 726 and the second internal interconnects 730 over the top substrate 728. The top encapsulation 604 may also cover top stacking vias 702. The top stacking vias 702 may extend from a top side of and through the top substrate 728. The top stacking vias 702 is connected and aligned with the conductive bumps 738 which is connected and aligned with the bottom stacking vias 724 forming stacking via interconnects 732.

The top substrate 728 includes contact pads 744 at a bottom side of the top substrate 728. Each of the contact pads 744 has a pad width 746. The bump width 740 is 50% or less than the pad width 746 thereby allowing for a fine pitch between the stacking via interconnects 732 as opposed to the larger pitch forced by traditional solder balls (not shown).

Referring now to FIG. 8, therein is shown a cross-sectional view of an integrated circuit package-on-package system 800 exemplified by the top view of FIG. 6 in a fifth embodiment of the present invention. The integrated circuit package-on-package system 800 includes structural similarities to the integrated circuit package-on-package system 600 of FIG. 7. The cross-sectional view depicts a bottom integrated circuit package system 810 stacked below a top integrated circuit package system 812. External interconnects 814, such as solder balls, may attach below the bottom integrated circuit package system 810.

Conductive bumps 838, such as micro bumps, are applied over bottom stacking vias 824 of the bottom integrated circuit package system 810. Each of the conductive bumps 838 has a bump width 840. The conductive bumps 838 may provide a number of functions. For example, the conductive bumps 838 provide electrical connection between the top integrated circuit package system 812 and the bottom integrated circuit package system 810. The conductive bumps 838 may also provide a gap 842 between the top integrated circuit package system 812 and the bottom integrated circuit package system 810 for airflow for helping cool the integrated circuit package-on-package system 800. The bump width 840 is approximately the same as a bottom via width of the bottom stacking vias 824.

Top stacking vias 802 of the top integrated circuit package system 812 may extend from a top side of and through a top substrate 828. The top stacking vias 802 is connected and aligned with the conductive bumps 838 which is connected and aligned with the bottom stacking vias 824 forming stacking via interconnects 832.

An adhesive 834, such as an adhesive film, is applied over the top side of a bottom encapsulation 822 of the bottom integrated circuit package system 810. The adhesive 834 do not impede the connections of the conductive bumps 838 with the top stacking vias 802 and the bottom stacking vias 824. The adhesive 834 may provide mechanical rigidity to the structure of the integrated circuit package-on-package system 800.

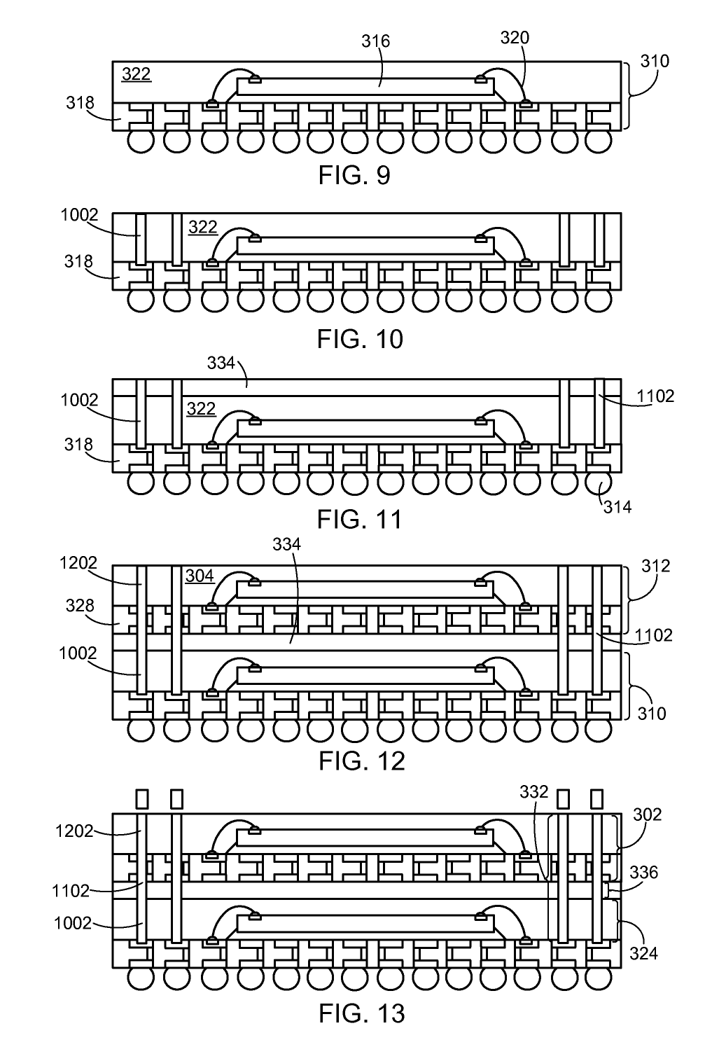

Referring now to FIG. 9, therein is shown a cross-sectional view of the integrated circuit package-on-package system 300 of FIG. 3 in a step of forming the bottom integrated circuit package system 310. The bottom integrated circuit package system 310 includes the bottom encapsulation 322 covering the first integrated circuit 316 and the first internal interconnects 320 over the bottom substrate 318. The bottom integrated circuit package system 310 may be tested ensuring known good device (KGD) without assembly into the integrated circuit package-on-package system 300.

Referring now to FIG. 10, therein is shown the structure of FIG. 9 in a step of forming bottom channels 1002. The bottom channels 1002 are formed into the bottom encapsulation 322 to the conduction portion of the bottom substrate 318 without traversing the bottom substrate 318. The bottom channels 1002 may traverse through the bottom substrate 318, as an example. The bottom channels 1002 may be formed in a number of ways. For example, the bottom channels 1002 may be formed with laser ablating with x-ray or infrared monitoring.

Referring now to FIG. 11, therein is shown the structure of FIG. 10 in a step of applying the adhesive 334 and attaching the external interconnects 314. The adhesive 334 is applied over the top side of the bottom encapsulation 322. Holes 1102 may be preformed in the adhesive 334 and aligned with the bottom channels 1002 or the holes 1102 may be formed after application of the adhesive 334 over the bottom encapsulation 322. The external interconnects 314 are also attached to and below the bottom substrate 318. A reflow process may be used to attach the external interconnects 314.

Referring now to FIG. 12, therein is shown the structure of FIG. 11 in a step of mounting the top integrated circuit package system 312. The top integrated circuit package system 312 mounts over the adhesive 334. The top integrated circuit package system 312 may be tested ensuring known good device (KGD) without assembly into the integrated circuit package-on-package system 300 of FIG. 3. Top channels 1202 traverse the height of the top integrated circuit package system 312 through the top encapsulation 304 and the top substrate 328. The top channels 1202 align with the holes 1102 and the bottom channels 1002. The top channels 1202 may be formed in a process similar to the one used to form the bottom channels 1002 and may be formed before mounting or after mounting the top integrated circuit package system 312 over the bottom integrated circuit package system 310.

Referring now to FIG. 13, therein is shown the structure of FIG. 12 in a step of plating the channels. The top channels 1202, the holes 1102, and the bottom channels 1002 are plated forming the top stacking vias 302, the connecting vias 336, and the bottom stacking vias 324, respectively, to collectively form the stacking via interconnects 332 and the integrated circuit package-on-package system 300 of FIG. 3.

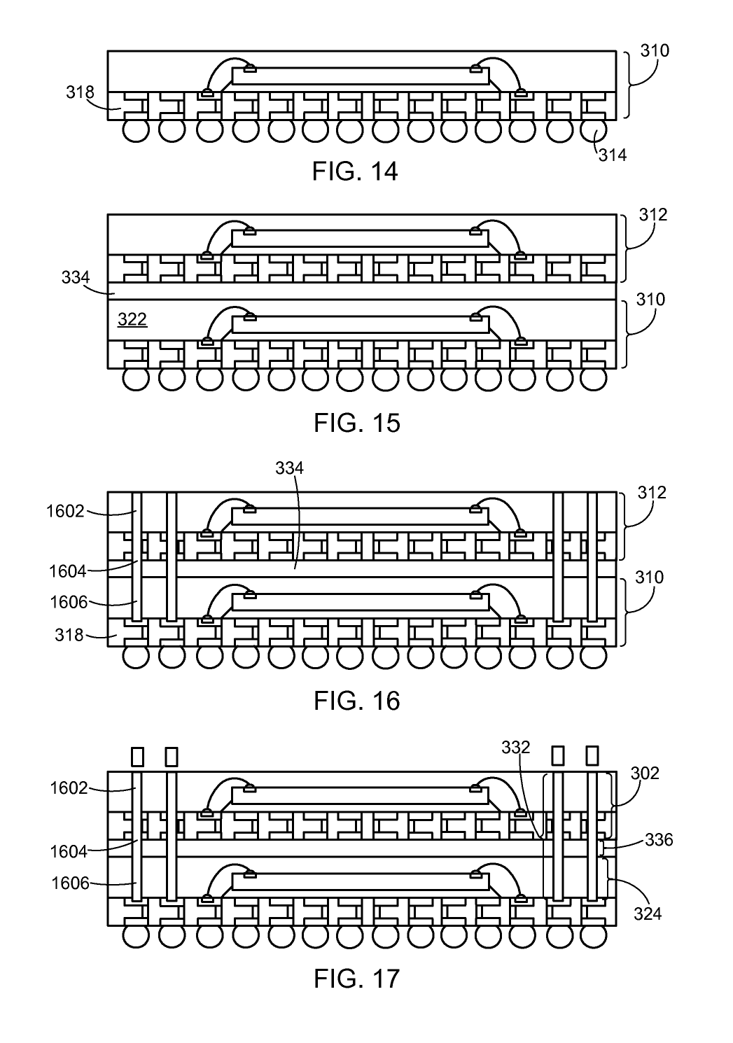

Referring now to FIG. 14 is the structure of FIG. 9 in a step of attaching the external interconnects 314. The step provides a different path for forming the integrated circuit package-on-package system 300 of FIG. 3 than that described from FIG. 9 through FIG. 13. The external interconnects 314 are attached to and below the bottom substrate 318 of the bottom integrated circuit package system 310. A reflow process may be used to attach the external interconnects 314.

Referring now to FIG. 15, therein is shown the structure of FIG. 14 in a step of mounting the top integrated circuit package system 312. The adhesive 334 is applied over the top side of the bottom encapsulation 322. The top integrated circuit package system 312 mounts over the adhesive 334 and the bottom integrated circuit package system 310. The top integrated circuit package system 312 may be tested ensuring known good device (KGD) without assembly into the integrated circuit package-on-package system 300 of FIG. 3. The adhesive 334 provides mechanical support to the stacking structure.

Referring now to FIG. 16, therein is shown the structure of FIG. 15 in a step of forming the channels. Top channels 1602, holes 1604, and bottom channels 1606 may be formed in through the top integrated circuit package system 312, the adhesive 334, and into the bottom integrated circuit package system 310 to the conductive portion of the bottom substrate 318, respectively. The top channels 1602, the holes 1604, and the bottom channels 1606 may be formed in a single step using laser ablating and monitored by x-ray or infrared. The single step process forms a self-aligning channel structure and held in place by the adhesive 334.

Referring now to FIG. 17, therein is shown the structure of FIG. 16 in a step of plating the channels. Similar to FIG. 13, the top channels 1602, the holes 1604, and the bottom channels 1606 are plated forming the top stacking vias 302, the connecting vias 336, and the bottom stacking vias 324, respectively, to collectively form the stacking via interconnects 332 and the integrated circuit package-on-package system 300 of FIG. 3.

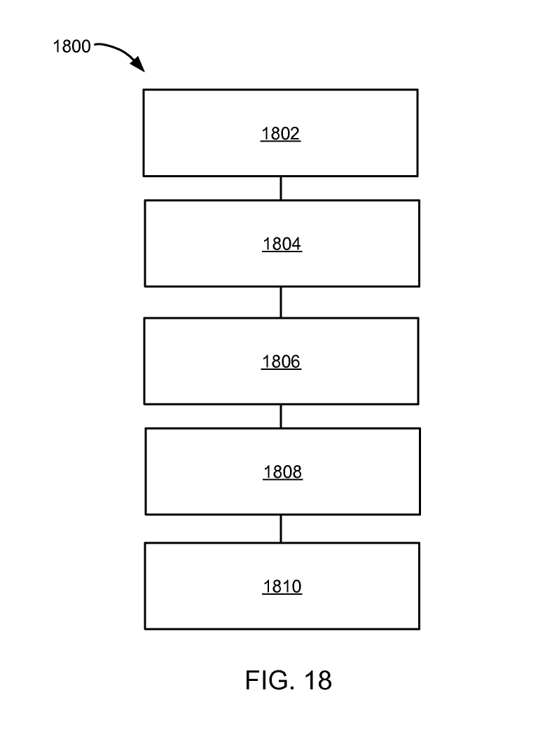

Referring now to FIG. 18, therein is shown a flow chart of an integrated circuit package-on-package system 1800 for manufacturing the integrated circuit package-on-package system 100 in an embodiment of the present invention. The system 1800 includes providing a bottom integrated circuit package system having a bottom substrate in a block 1802; mounting a top integrated circuit package system having a top substrate over the bottom integrated circuit package system in a block 1804; forming a top stacking via through the top substrate in a block 1806; forming a bottom stacking via into the bottom integrated circuit package system to the bottom substrate in a block 1808; and forming a stacking via interconnect with the top stacking via and the bottom stacking via aligned and connected in a block 1810.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit package-on-package system of the present invention furnishes important and heretofore unknown and unavailable solutions, capabilities, and functional aspects for improving yield, increasing reliability, and reducing cost of circuit system. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. An integrated circuit package-on-package system comprising:
providing a bottom integrated circuit package system having a bottom substrate;
mounting a top integrated circuit package system having a top substrate over the bottom integrated circuit package system;
forming a top stacking via through the top substrate;
forming a bottom stacking via into the bottom integrated circuit package system to the bottom substrate; and
forming a stacking via interconnect with the top stacking via and the bottom stacking via aligned and connected.

2. The system as claimed in claim 1 further comprising:
applying an adhesive having a connecting via over the bottom integrated circuit package system with the connecting via aligned with the bottom stacking via; and
wherein forming the stacking via interconnect includes:
plating the connecting via aligned with the top stacking via.

3. The system as claimed in claim 1 wherein forming the stacking via interconnect includes attaching a conductive bump between the top integrated circuit package system and the bottom integrated circuit package system.

4. The system as claimed in claim 1 further comprising:
applying an adhesive over the bottom integrated circuit package system; and wherein forming the stacking via interconnect includes:
attaching a conductive bump between the top integrated circuit package system and the bottom integrated circuit package system with the conductive bump adjacent to the adhesive.

5. The system as claimed in claim 1 wherein forming the top stacking via through the top substrate includes forming the top stacking via through the top integrated circuit package system.

6. An integrated circuit package-on-package system comprising:
providing a bottom integrated circuit package system having a bottom encapsulation over a bottom substrate;
mounting a top integrated circuit package system having a top encapsulation over a top substrate over the bottom integrated circuit package system;
forming a top stacking via through the top substrate;
forming a bottom stacking via into the bottom integrated circuit package system through the bottom encapsulation to the bottom substrate; and
forming a stacking via interconnect with the top stacking via and the bottom stacking via aligned and plated.

7. The system as claimed in claim 6 wherein forming the top stacking via through the top substrate includes forming the top stacking via through the top encapsulation.

8. The system as claimed in claim 6 wherein forming the top stacking via and forming the bottom stacking via includes forming both the top stacking via and the bottom stacking via in a single step for a self-aligning the top stacking via with the bottom stacking via.

9. The system as claimed in claim 6 wherein forming the stacking via interconnect includes not covering the stacking via interconnect with the top encapsulation.

10. The system as claimed in claim 6 further comprising attaching an external interconnect to and below the bottom substrate.

11. An integrated circuit package-on-package system comprising:
a bottom integrated circuit package system having a bottom substrate with a bottom stacking via into the bottom integrated circuit package system to the bottom substrate;
a top integrated circuit package system having a top substrate over the bottom integrated circuit package system with a top stacking via through the top substrate; and
a stacking via interconnect with the top stacking via and the bottom stacking via aligned and connected.

12. The system as claimed in claim 11 further comprising:
an adhesive having a connecting via over the bottom integrated circuit package system with the connecting via aligned with the bottom stacking via; and
wherein the stacking via interconnect includes:
the connecting via aligned with the top stacking via.

13. The system as claimed in claim 11 wherein forming the stacking via interconnect includes a conductive bump between the top stacking via and the bottom stacking via.

14. The system as claimed in claim 11 further comprising:
an adhesive over the bottom integrated circuit package system; and wherein the stacking via interconnect includes:
a conductive bump between the top stacking via and the bottom stacking via with the conductive bump adjacent to the adhesive.

15. The system as claimed in claim 11 wherein the top stacking via through the top substrate includes the top stacking via through the top integrated circuit package system.

16. The system as claimed in claim 11 wherein:
the bottom integrated circuit package system includes a bottom encapsulation over the bottom substrate with the bottom stacking via through the bottom encapsulation to the bottom substrate; and
the top integrated circuit package system includes a top encapsulation over the top substrate.

17. The system as claimed in claim 16 wherein the top stacking via through the top substrate includes the top stacking via through the top encapsulation.

18. The system as claimed in claim 16 wherein the top stacking via and the bottom stacking via are self-aligned.

19. The system as claimed in claim 16 wherein the top encapsulation is not over the stacking via interconnect.

20. The system as claimed in claim 16 further comprising an external interconnect to and below the bottom substrate.
